(19) United States
(12) Patent Application Publication
(10) Pub. No.: US 2026/0073965 A1
(43) Pub. Date: Mar. 12, 2026

(54) MEMORY DEVICE

(71) Applicant: Ferroelectric Memory GmbH, Dresden (DE)

(72) Inventors: Luigi Paone, Pioltello (IT); Mauro Pagliato, Bollate (IT); Alessandro Palludo, Milan (IT)

(21) Appl. No.: 18/830,668

(22) Filed: Sep. 11, 2024

(51) Int. Cl. G11C 11/22

(52) U.S. Cl. CPC G11C 11/2297; G11C 11/221; G11C 11/2273; G11C 11/2275; G11C 11/2293

(57) ABSTRACT

Disclosed herein is memory device, comprising a set of memory cells provided in a plateline connected configuration; a cell operation circuit coupled to a memory cell of the set via a bitline, wherein the cell operation circuit is configured, in a read operation mode, to read from the memory cell based on an operation voltage level; a control circuit configured to control a power supply voltage supplied to the cell operation circuit in accordance with a powering sequence when initiating the read operation mode, wherein the powering sequence comprises: a first phase, in which the power supply voltage is increased to a pre-charge voltage level being lower than the operation voltage level, and a second phase, in which the power supply voltage is increased to the operation voltage level.

### TECHNICAL FIELD

This disclosure relates to non-volatile memories, and in particular, to memories that include state-programmable memory elements for storing information in a memory cell.

### BACKGROUND

Non-volatile memories allow for storing information in a memory, where the stored information is retained in the memory even after external power to the memory has been removed. Memories are typically formed from a number of memory cells, where each memory cell is able to store information in a state-programmable memory element (e.g., a ferroelectric memory element such as a ferroelectric capacitor) that is capable of retaining the written information based on a programmed state of the state-programmable memory element that is retained even after its power source has been removed. The programmed state usually represents a binary value (e.g., a logic “1” or a logic “0”) that may be read out at later time by applying a read voltage sufficient to switch the state of the state-programmable memory element, and then determining the read state from the switching charge injected when the state-programmable memory element changes states. However, conventional configurations suffer from various deficiencies, leading to potential read errors.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A shows an exemplary memory cell including a state-programmable memory element and FIG. 1B shows a graph of an exemplary hysteresis curve of such a state-programmable memory element;

FIG. 2A to FIG. 2C show each a device in a schematic circuit diagram;

FIG. 3A, FIG. 11A and FIG. 12A show each a cell operation circuit in a schematic circuit diagram;

FIG. 3B, FIG. 5A, FIG. 11B and FIG. 12B show each an operation schema in a schematic diagram;

FIG. 5B shows a device in a schematic circuit diagram;

FIG. 6A shows an operation schema in a schematic diagram, detailing the time dependency of various signals;

FIG. 6B shows a power modification circuit in a schematic circuit diagram;

FIG. 7A and FIG. 4 show each an exemplarily implementation of the power modification circuit in a schematic circuit diagram;

FIG. 7B and FIG. 8A show each an operation schema in a schematic diagram;

FIG. 8B shows an exemplarily implementation of a device detailed herein in a schematic circuit diagram;

FIG. 9A to FIG. 9C show each an exemplarily implementation of various circuits detailed herein in a schematic circuit diagram; and

FIG. 10A and FIG. 10B show each an exemplary memory cell arrangement in a schematic diagram.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices. However, it may be understood that aspects described in connection with methods may similarly apply to the devices, and vice versa.

In general, the term “bit” (also referred to as digital bit or as binary digit) relates to the fundamental unit of information storage, transmission and processing. The value of a bit represents a logical state selected from only two logical states, which are commonly referred to as “0 ” or “1”, or as “on” and “off”. In context of information storage, each of these logical states may be represented by a physical state (also referred to as programmed state or memory state) of a state-programmable memory element, e.g., the polarization direction of the memory element.

The term “switch” (also referred to as switch circuitry) relates to a circuitry including two terminals and a connection between the two terminals. The switch is configured to change an impedance (e.g., resistance) of the connection, e.g., in a controlled manner and/or as a function of a signal (e.g., control signal) to which the switch (e.g., a control terminal thereof) is exposed. For example, the impedance (e.g., resistance) of the connection may be decreased, when the voltage of the control signal increases, and increased otherwise. Herein, the switch is implemented by one or more transistors (e.g., a gate terminal being supplied with the control signal), which is understood as not limiting. The references made hereto may apply in analogy to any other implementation of the switch.

In general, a non-volatile memory device is typically formed from a number of memory cells, where each memory cell typically stores one of two (e.g., logical) states: a first state representing the off state (e.g., representing a digital bit of “0”) and a second state representing the on state (e.g., representing a digital bit of “1”). The individual memory cells of the memory are typically organized into control groupings of cells (also referred to as set), where each cell may be individually addressed but have a common operation scheme for biasing the cells via control lines such as bitlines (e.g., for operating the cells grouped in the same column), wordlines (e.g., for operating cells grouped in the same row), and/or platelines (e.g., for operating cells grouped so as to share a common node such as a same “plate”). Among other components, a memory cell may include a state-programmable memory element (e.g., a ferroelectric memory element such as a ferroelectric capacitor) that is capable of retaining the written information by writing one of the remanent states of the memory element so that it may be read out at a later time during a read operation.

As used throughout this disclosure, a state of a memory element is described as “remanent” where the memory element is capable of retaining its programmed state even when it is not connected to a power source. As also used throughout, the current remanent state to which the memory element has been set may be referred to as the “stored” state, the “written” state, or the “programmed” state. As should be understood, when referring to a state-programmable memory element, the terms “write,” “store,” or “program” are used generically to refer to setting the remanent state of the state-programmable memory element(s). As is understood, the term “voltage” (also referred to as electrical potential difference), e.g., with respect to “a bitline voltage”, “a wordline voltage,” “a plateline voltage,” and the like, may refer to an electrical potential, e.g., its value with respect to a reference potential (e.g., ground). The “voltage across” a component may be used herein to denote a voltage drop from a node on one side of a component (e.g. one side of a capacitor) to a node on the other side of the component (e.g., the other side of the capacitor).

When a state-programmable memory element includes ferroelectric material (e.g., a ferroelectric capacitor), the remanent state is understood as referring to a remanent polarization state that is set by applying a particular voltage across the element that is sufficient to set a corresponding polarization state, where, once set, the remanent polarization state is retained by the element even when the voltage across the element has been removed (e.g., it is remanently-polarizable). Once such an element has been state-programmed to a remanent state, it generally retains the programmed state until it is re-programmed by applying a voltage across it that is sufficient to program the element to a (e.g., new) remanent state. A polarization capability of a state-programmable memory element (e.g., remanent polarization capability, e.g., non-remanent spontaneous polarization capability) may be analyzed using capacity measurements (e.g., a spectroscopy), e.g., via a static (C-V) and/or time-resolved measurement or by polarization-voltage (P-V) or positive-up-negative-down (PUND) measurements. Another method for determining a polarization capability of a state-programmable memory element may include transmission electron microscopy, e.g., an electric-field dependent transmission electron microscopy.

As noted above, a memory device (shortly also referred to as memory) includes multiple memory cells, of which each memory cell contains a memory element that represents information by being programmable to different states, each state corresponding to different stored information (e.g., a stored value of a digital bit of “0 ” may be represented by a first programming state and a digital bit of “1” may be represented by a second programming state). Once the memory element of the memory cell has been programmed (also referred to as write operation), the programmed state may be read out (also referred to as read operation) by initiating a read operation mode. In the read operation mode, a read voltage may be applied to the memory element that is sufficient to switch its programmed state and develop a charge (also referred to as switching charge) in a cell operation circuit, a sensed voltage of which may then be compared to a threshold reference voltage to determine the programmed state (also referred to as memory state).

A cell operation circuit may include or may be implemented by a sense circuit, e.g., a sense amplifier as sense circuit, to which this disclosure refers to without limitation thereof. It may be understood that all other architectures of cell operation circuits (also referred to as sensing architectures) may be used, to which the references made herein apply in analogy. Various implementations of a cell operation circuit, e.g., the sense amplifier thereof, are configured to amplify a voltage swing initiated by the switching charge to a certain level, which can be interpreted properly by a circuit outside the memory. For example, the sense amplifier may be implemented by a latch, which is described later in detail.

With certain memory cell configurations, sensing architectures, and memory elements, there may be a parasitic coupling between the bitlines, e.g., via the plateline, and thus a parasitic coupling across multiple state-programmable memory elements (e.g., where one terminal is connected to the bitline, typically through an access transistor, and the other terminal is connected to the plateline). Thus, when one or more bitlines are charged, the parasitic coupling may develop a parasitic voltage at another bitline. The more bitlines contribute to this parasitic voltage, the higher the level of this parasitic voltage may be. A higher level of the parasitic voltage reduces the width of the read window (e.g., the difference between the developed voltage associated with a “0 ” bit and the developed voltage associated with a “1” bit) and the read margin may be reduced, leading to potential read errors.

As example, the parasitic voltage developed on the bitline due to the parasitic coupling may influence the cell operation circuit, which is configured, in a read operation mode, to read (e.g., the memory state) from the memory cell. When the parasitic voltage exceeds a certain threshold, the cell operation circuit may read a logical 1, irrespective of the actual memory state of the memory cell. This may lead to the risk of a reading error, which increases with the number of memory cells having the same memory state.

This parasitic coupling may particularly exist in a memory with an “all bitline” (ABL) architecture, where multiple (e.g., all) bitlines in a group may be read simultaneously by applying a read voltage to a plateline that is common to the group and then sensing the charge developed on each memory element's corresponding bitline, meaning that all bitlines of the group may contribute to the parasitic voltage when being read out simultaneously.

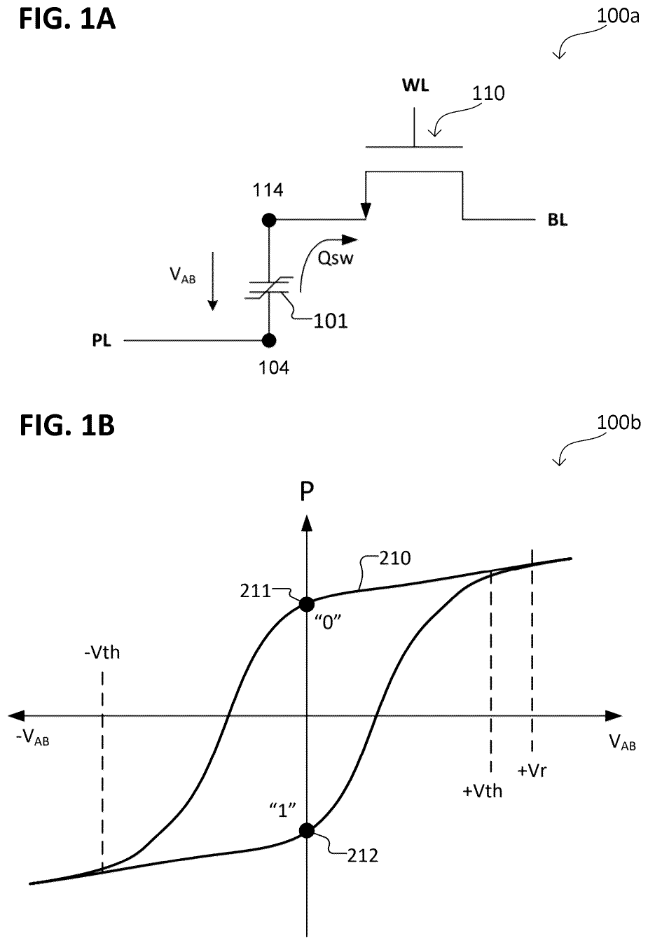

FIG. 1A shows an exemplary memory cell 100a including a state-programmable memory element 101 and an access transistor 110; and FIG. 1B shows a graph 100b of an exemplary hysteresis curve 210 of such a state-programmable memory element 101 (e.g., state-programmable memory element 101). The memory element 101 includes a first terminal 104 (also referred to as plateline terminal), which is configured to be connected to the plateline (PL) of the memory. The memory element 101 includes a second terminal 114 (also referred to as bitline terminal), which is configured to be connected to the bitline (BL) of the memory through the access transistor 110. The access transistor 110 may be configured to be controlled by a wordline (WL) of the memory, e.g., as the gate of the access transistor 110 is exposed to a voltage of the wordline, WL.

An exemplary implementation of a read operation scheme includes to discharge the bitline BL (e.g., to ground) and then increase the voltage of the PL terminal to a read voltage VPL, at which a switching charge Qsw is provided from the state-programmable memory element to the bitline terminal 114. If the access transistor is active, the switching charge Qsw is developed onto the bitline BL, thereby causing a voltage swing (also referred to as switching voltage) at the bitline BL, which is a function of the programmed state of the state-programmable memory element 101 and its dielectric capacitance. The developed switching voltage may be processed by a cell operation circuit, which is coupled to BL. For example, the switching voltage is compared to a predetermined threshold voltage to determine the read state (e.g., the logic state, e.g., a “0” or a “1”) of the corresponding memory cell.

FIG. 1B shows a graph 100b of an exemplary hysteresis curve 210 of a state-programmable memory element (e.g., the state-programmable memory element 101 of FIG. 1), where the polarization (P) of the state-programmable memory element is plotted as a function of the voltage applied across it (V_{AB}). In the case of the memory cell shown in FIG. 1A, the voltage applied across the state-programmable memory element is the difference in voltage between the plateline terminal 104 and the bitline terminal 114, e.g., expressed as a function of V_{PL}-V_{BL}. Graph 100b shows two remanent polarization states (211, 212) of the state-programmable memory element that may represent the programmable states of the memory element. For example, the state-programmable memory element may be programmed to remanent polarization state 211 (representing, for example, a bit of digital information with a value of “0”) or to remanent polarization state 212 (representing, for example, a bit of digital information with a value of “1”) by applying a programming voltage across the state-programmable memory element that is sufficient to program the corresponding remanent polarization state.

The programming voltage is defined by a (e.g., intrinsic) threshold voltage (Vth) of the state-programmable memory element, above which the state-programmable memory element is programmed to a corresponding remanent polarization state. For example, if the applied voltage across the state-programmable memory element is greater than +Vth (e.g., more positive than +Vth), the state-programmable memory element will be programmed to remanent polarization state 211. If the applied voltage across the state-programmable memory element is greater than −Vth (e.g., more negative than −Vth), the state-programmable memory element will be programmed to remanent polarization state 212. The hysteresis curve 210 shows the path the polarization follows as the voltage across the state-programmable memory element changes.

To read the stored state (also referred to as programmed state) of a state programmable memory element, a read voltage (e.g., +Vr being a function of VPL) is applied across the state-programmable memory element that is sufficient to program a remanent state of the state-programmable memory element to a predefined state. This develops the switching charge, which is a function of the programmed state before the read voltage was applied. In the first case, when the read voltage causes the state-programmable memory element to switch to a new state (e.g., the predefined state is different from the previously programmed state), the switching charge will be larger compared to the second case, when the read operation caused the state-programmable memory element to be re-programmed to the same state (e.g., the predefined state is the same as the previously programmed state). For example, in the second case, little or no switching charge will be provided from the state-programmable memory element.

To facilitate the understanding, the predefined state is assumed to be “0” herein, which is not limiting. The references made thereto apply analogously for a configuration, in which the predefined state is to be “1”.

As should be understood, the voltage of the bitline BL may also be a function of one or more parasitic (e.g., capacitive) couplings, e.g., the intrinsic dielectric capacitance of the state-programmable memory element 101, the capacitance of the conductors to which it is connected (e.g., the bitline), and the capacitive coupling to one or more other bitline BL and/or the plateline PL. As a result, the voltage of the bitline BL, which is processed by the cell operation circuit during a read operation, may depend not only on the switching charge but also on such capacitive couplings, the voltage level of the plateline and vice versa.

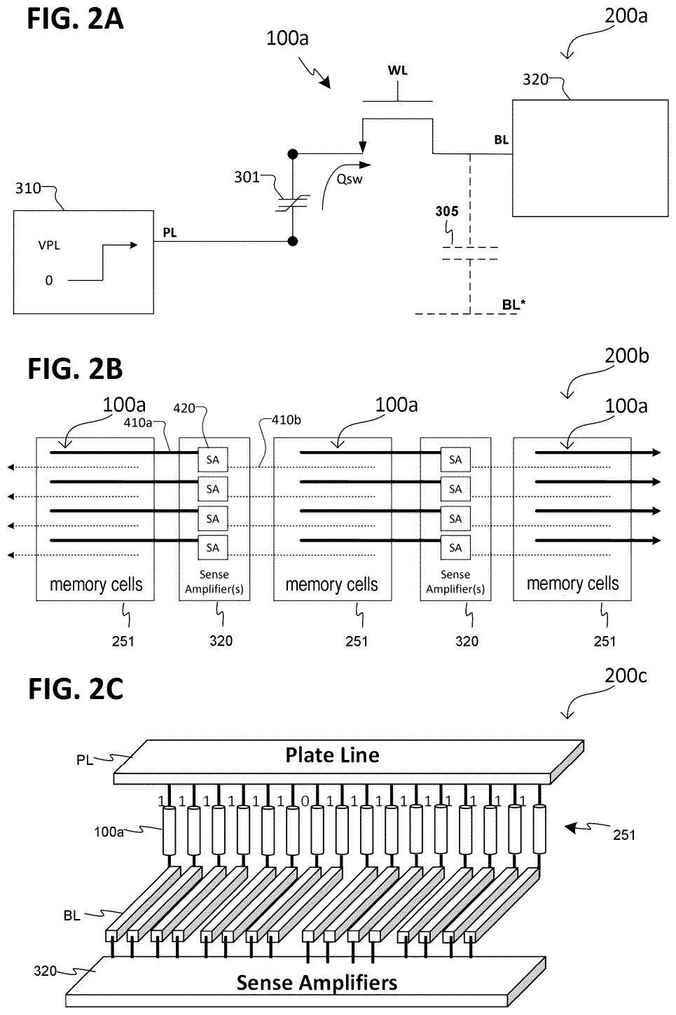

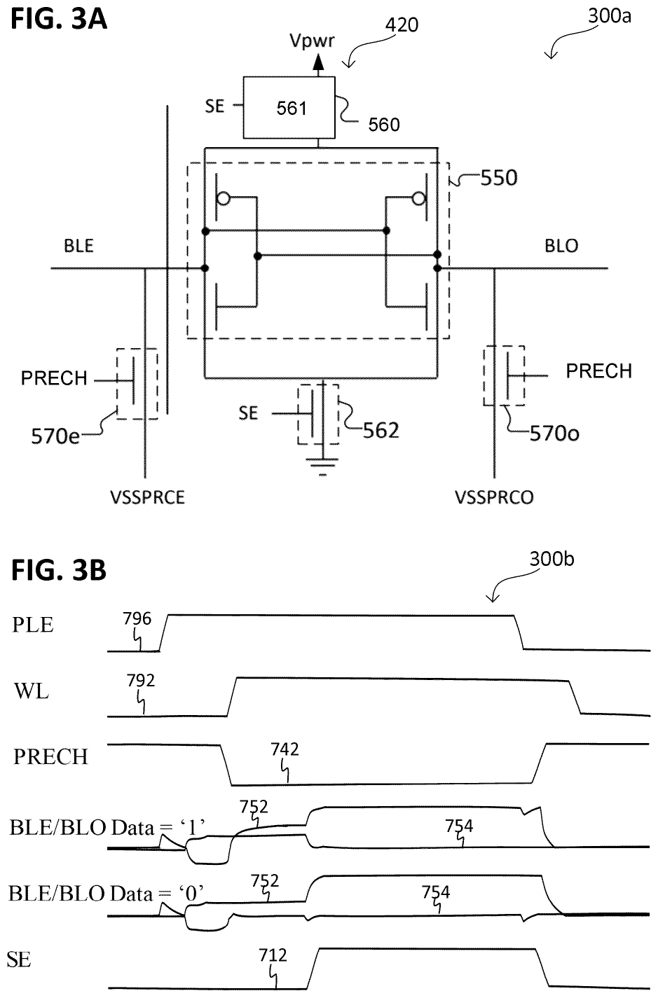

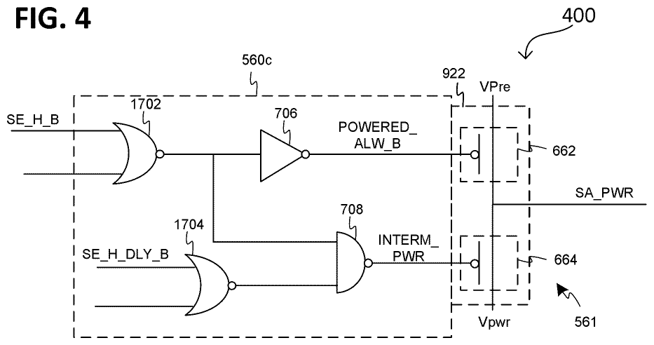

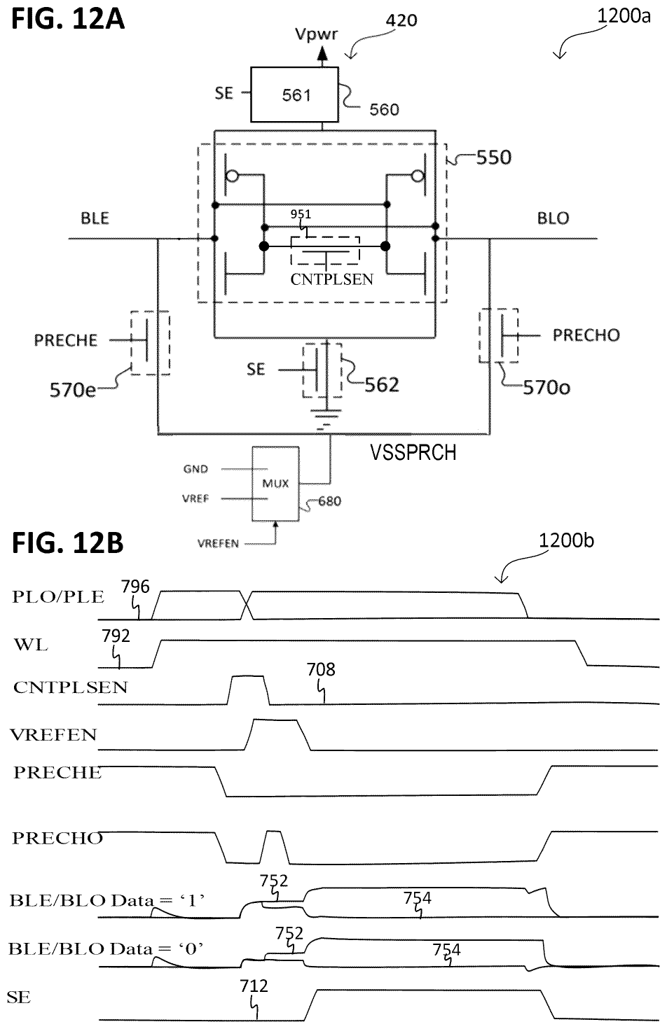

FIG. 2A shows a device 200a (e.g., memory device) in a schematic circuit diagram, the device 200a including the memory cell 100a, a cell operation circuit 320 (e.g., including one or more sense amplifiers 420, see also FIG. 3A) coupled to the bitline, BL, and a plate voltage source 310, coupled to the plateline, PL. Device 200a may further include a parasitic coupling 305 between the bitline, BL, to which the state-programmable memory element 301 connects via an access transistor controlled by the wordline, WL, and one or more other bitlines BL*, e.g., through the plateline, PL. More details of the parasitic coupling 305 are provided with respect to FIG. 10B.

In an exemplary read operation, the bitline BL may first be discharged to ground and then a read voltage is applied to the state-programmable memory element 101, e.g., by increasing the voltage of the plateline, PL, e.g., to +VPL. The read voltage is sufficient to program the state-programmable memory element 301 to a predefined remanent state (e.g., the state associated with “0,” e.g., shown in FIG. 1B as 211). The switching charge (Qsw) is then developed by the programmable memory element 301 through the access transistor to the bitline BL. Additionally, the bitline BL may be influenced via the parasitic coupling 305, e.g. as a function of the voltage level of the one or more other bitlines BL*.

As should be understood, a single sense amplifier may, for example, be connected to multiple memory elements that are part of the same set and therefore share a common bitline. Thus, the effective parasitic coupling 305 between the one or more other bitlines BL* and the bitline may be due to the multiple memory elements that share a common bitline. Alternatively or additionally, a sense amplifier 420 (see also FIG. 3A) may be differential or dual-sided, where one side of the sense amplifier 420is connected to one bitline of one set of memory cells (e.g., a bitline of an even set of cells) and the other side of the amplifier is connected to a bitline of a different set of memory cells (e.g., a bitline of an odd set of cells). In a dual-sided configuration, one side of the sense amplifier 420 may be actively operated to read a bitline of one set of cells (e.g., the even side) while the other side (its complement) of the amplifier acts as a reference (e.g., a bitline on the odd side), and vice versa.

FIG. 2B shows a device 200b (e.g., memory device) in a schematic circuit diagram, the device 200b including multiple sets 251 of memory cells 100a, and multiple cell operation circuits 320 in a complementary configuration (also referred to as dual-sided configuration), of which each cell operation circuit 320 includes a set of sense amplifiers (also referred to as bank) coupled to a bitline, BL. The complementary type uses dual-sided (also called complementary) sense amplifiers as shown in FIG. 2B, where each sense amplifier in a set of sense amplifiers may be connected, on one side of the dual-sided amplifier to a common bitline for one row in an “even” set of memory cells (shown by heavy, dark lines) and on the other side of the dual-sided sense amplifier to a common bitline for one row in an “odd” set of memory cells (shown by light, dotted lines). Illustratively, the light line of a given sense amplifier is complementary to the dark line. In FIG. 2B, eight sense amplifiers are shown in two different banks, where one sense amplifier 420 and its complementary “even” bitline 410a connected to one row of an “even” set of memory cells and its “odd” bitline 410b connected to one row of an “odd” set of memory cells are labeled. As should be appreciated, this type of pattern may repeat across the memory, where each memory cell array may have any number of rows of “even” sets of memory cells, each with a (e.g., complementary) row in the set of “odd” memory cells, where each sense amplifier connects, differentially, to an even/odd bitline pair. As should be understood, the terms “even” and “odd” are arbitrary groupings of memory cells to which the sense amplifier is connected and need not refer to any particular numbering scheme of even- and odd-numbered cells. More generally, the even/odd configuration or dual-sided configuration described herein may be understood as a complementary configuration, where one side of the amplifier is the side to be read while the other side serves as its complement. In a typical memory that has even and odd groupings of memory cells, the groupings may be, for example, layout-based.

FIG. 2C shows a device 200c (e.g., memory device) in a schematic circuit diagram, the device 200c including a set 251 of memory cells 100a including one or more first memory cells programmed to a first state (e.g., representing a digital bit of “0”), and a plurality of second memory cells, of which each is programmed to a second state (e.g., representing a digital bit of “1”). For example, the ratio (also referred to as cell state ratio) of the number of second memory cells to the number of first memory cells is 10 or more, e.g., 10² or more, e.g., 10³ or more, e.g., 10⁴ or more.

FIG. 3A shows a part of cell operation circuit 320 of a complementary type including a sense amplifier 420 in a schematic circuit diagram 300a. In a dual-sided configuration, the sense amplifier may be implemented by a latch 550. The latch 550 of the exemplary dual-sided configuration includes a first input (e.g., the “even” input) connected to an even bitline (BLE) and a second input (e.g., the “odd” input) connected to an odd bitline (BLO). The latch 550 may be powered via one or more switches 561, 562 (also referred to as the power modification switches 561, 562), e.g., transistors, of a power modification circuit 560. The power modification circuit 560 may be controlled by one or more sense enable (SE) signals provided to or by a control circuit, as described later in detail.

The power modification switches 561, 562, when enabled, connect one side of the latch 550 to an operation voltage level (Vpwr), and the other side of the latch 550 to ground (or another reference voltage level). To initiate a read operation mode, the power modification switches 561, 562 may be operated by the one or more sense enable (SE) signals to apply the operation voltage level, Vpwr, to latch 550, e.g., when the SE signal is enabled. Before and/or after the read operation mode, the power modification switches 561, 562 may be operated by the one or more sense enable (SE) signals to leave the latch 550 floating (also referred to as inactive latch 550), when the SE signal is not enabled.

Even and odd pre-charging control (PRC) switches (570e, 570o), e.g., implemented by respective transistors (also referred as to PRC transistors), may be operated by a single corresponding signal (PRECH) that, when enabled, causes the corresponding bitline to be connected to its corresponding even/odd source voltage (VSSPRCE, VSSPRCO) for charging and/or discharging the corresponding bitline. As reflected by the exemplary implementation of FIG. 3A, the PRC transistors 570e, 570o may share their gate control line, thus being exposed to the same PRC (pre charge control) signal (also referred as to PRECH). Further, the source voltage (also referred as to net voltage) used for biasing the bit lines, BLO/BLE, may be provided individually, e.g., providing an even net voltage, VSSPRCE, used for biasing the even bit line (BLE), and an odd net voltage, VSSPRCO, used for biasing the odd bit line (BLO).

FIG. 3B show an operation schema in a schematic diagram for the cell operation circuit 320 of FIG. 3A or another implementation of cell operation circuit 320 that may be dual-sided, and includes, similar to FIG. 3A, a latch 550.

Referring to FIG. 3B, the read operation starts by enabling one or more word line(s), WL(s), (see line 792) associated with the cell(s) to be read in the read operation mode. This enables the corresponding access transistor that connects one side of the memory element(s) to the corresponding bitline (see FIG. 2A).

Starting at the top of the diagram, the first and second segments plot the voltages on the wordline (WL, plotted along line 792), and the plateline (PLE, plotted along line 796). The third segment plots the pre charge control signal (PRECH, along line 742) that, when at logic high, connects the bitlines to VSSPRCE/VSSPRCO, and, when at logic low, leaves the bitlines floating. The next segments plot the voltage on the even bitline (BLE, along line 752) and the odd bitline (BLO, along line 754), for two cases, of which the upper represents a logic information of “1” (e.g., logic high) and the lower represents a logic information of “0” (e.g., logic low). The last segment shows the voltage on the sense enable control signal (SE, plotted along line 712) that enables the sense amplifier 420 when set to logic high.

Separated even/odd VSSPRCH voltages (also referred as to VSSPRCHE and VSSPRCHO) are provided together with a common PRC (pre charge control) signal (PRECH). The odd side plateline, PLO, is always deselected (e.g., being at logical low). Both bitlines (BLE/BLO) are kept grounded by the respective PRC transistors 570e, 570o, e.g., until the disturbance initiated by the increasing PLE voltage is recovered. The bitlines (BLO and BLE) may be biased to different values, e.g., to VREF for BLO and to GND for BLE, or to VREF for BLO and to VCNTPLS for BLE. During operation, the selected wordline (WL) is opened, which causes a voltage to develop on the even bitline BLE. Setting the sense enable control signal (SE) to logic “high” causes turning on the sense amplifier (SA), e.g., latch 550. As result, the reading operation may be conducted, e.g., by sensing a voltage difference by the SA. Implementing further aspects as detailed herein, e.g., the power modification circuit 560, improves the reading operation.

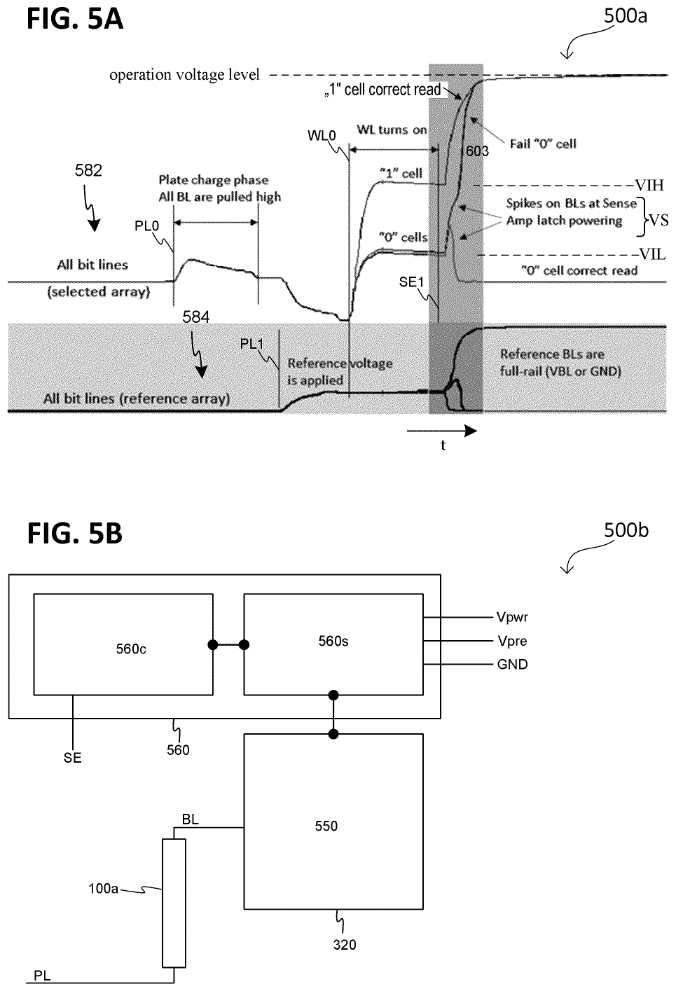

FIG. 5A shows an operation schema 500a similar to that of FIG. 3B, e.g., applied to the sense amplifier 420 of FIG. 3A (e.g., implemented in device 200b and/or 200c), additionally detailing for the above case of a logic information of “0” (e.g., logic low), a reading error.

Summarized, lines 582 represent the voltage level of all the bitlines in the selected array (BLE for example), which are reduced at time PL1 (e.g., developed to a negative voltage), e.g., as a counter pulse is applied. Analogously, lines 584 represent the voltage level of all the bitlines in the reference array (BLO for example) being increased at time PL1 to a reference voltage. For such implementation, the two pre charge control signals (PRECHE and PRECHO) may be enabled at the same time, and two individual even/odd source voltages (VSSPRCE/VSSPRCO) may be connected to the bit lines, BL. Please note, the implementation 400 detailed in FIG. 4, for example, includes a common source voltages VSSPRC, which would not result in such time dependency of the voltage levels.

Lines 582 of the schema 500a represent all the bitlines in the selected array (BLE, for example) developing a voltage drop to a negative voltage level at t=PL1 (e.g., as a counter-pulse is applied). Lines 584 of the schema 500a represent all the bitlines in the reference array (BLO for example) developing a voltage increase to a reference voltage level. At the same time, the PRECH signal is enabled, and separate VSSPRCE/VSSPRCO signals are connected to the BLs.

As outlined above, the read operation scheme may include multiple phases (also referred to as operation phases). In a first operation phase, which starts at t=PL0, the plateline, PL, is charged (e.g., to VPL), which increases the voltage of the bitlines, BL, coupled to the cell operation circuit 320 and to the set of memory cells selected for read out (also referred to as selected array). In a third operation phase, which starts at t=WL0, the read operation starts by enabling the wordlines, WL, coupled to the set of memory cells selected for read out.

As detailed above, each memory cell (e.g., ferroelectric cell) of the set of memory cells selected for read out may be coupled, via a BL, to a latch 550. Optionally, the latch 550 may be provided in the complementary type, e.g., being further coupled to a complementary memory cell, via a complementary bitline as reference BL, of a set of complementary memory cells (also referred to as reference array).

The latch 550 is inactive (e.g., floating) until the end of the third operation phase, e.g., as both power and ground supplies are Hi-Z. In a fourth operation phase, e.g., starting at or shortly after t=SE1, e.g., when enough signal separates the BL from the reference BL, the latch 550 is powered (also referred to as initiated or as initiating the read operation mode), e.g., by setting the SE signal to high, and its nodes are driven rail to rail.

As detailed above, the parasitic coupling between multiple bitlines, BL, via the plateline, PL, may cause the risk of a read error in specific scenarios (also referred to as error prone scenarios, see also See also FIG. 2C). To facilitate the understanding of such error prone scenarios, the exemplary configuration of the set of memory cells (e.g., ferroelectric cells) selected for read out includes two or more first memory cells (also referred to as “0” cell) programmed to a first state (e.g., representing a digital bit of “0”), and a plurality of second memory cells (also referred to as “1” cell), of which each memory cell is programmed to a second state (e.g., representing a digital bit of “1”). As being understood, this exemplary configuration is not limiting and the references made in this context, may apply in analogy to another cell state ratio, e.g., of 10 or more, e.g., 10² or more, e.g., 10³ or more, e.g., 10⁴ or more.

A first latch coupled to a “0” cell via a first bitline, BL, is exposed to a lower intermediate voltage level of the first bitline, than a second latch coupled to a “1” cell via a second bitline, BL* (see also FIG. 2A). In normal operation, a latch coupled to a “1” cell charges the second bitline, BL*, from the “high” intermediate voltage (VIH) level to the operation voltage level (see line indicated as “1” cell correct read) supplied to the latch 550, e.g., to Vpwr. Analogously, a latch 550 coupled to a “0” cell discharges the first bitline, BL, from the “low” intermediate voltage level (VIL) to the reference voltage (see line indicated as “0” cell correct read) supplied to the latch 550, e.g., to GND.

In the error prone scenario, many digital bit of “1” are read simultaneously, when the latches 550 are powered by the operation voltage level. Thus, many bitlines, BL, will be charged from the “high” intermediate voltage, VIH, to the operation voltage level (see line indicated by “1” cell correct read), e.g., to Vpwr. However, due to the coupling of each bitline, BL, to the plateline, PL, the charging to operation voltage level causes a glitch at the plateline itself, creating positive feedback to all other bitlines. For example, a latch 550 coupled to a “0” cell via the first bitline will be exposed to a parasitic voltage developed from this feedback. Illustratively, the feedback via the plateline increases the voltage of the first bitline, BL, from the “low” intermediate voltage level to a voltage level, VS, between VIL and VIH.

When the voltage level of the first bitline coupled to a “0” cell is increased to a level below the critical threshold level (e.g., the threshold reference voltage), it will be decreased normally, e.g., showing a voltage spike (also referred to as BL spike). When the voltage level of the first bitline coupled to a “0” cell is increased to a level above the critical threshold level, it will be increased abnormally (also referred to as abnormal voltage raise), e.g., to the operation voltage level (see line indicated as Fail “0” cell). Such “0” cell will be read incorrectly as “1” cell, instead of “0” cell, as a weak “0” BL is subject to a strong positive coupling.

Various aspects detailed herein address this risk of incorrectly read as outlined in the following.

FIG. 5B shows a device 500b (e.g., memory device) in a schematic circuit diagram, the device 500b including one or more memory cells 100a, a cell operation circuit 320 (e.g., including a latch 550 as sense amplifier) coupled to the memory cell 100a via a bitline, BL, a power modification circuit 560 including a control circuit 560c and multiple driver devices 560s (e.g., including multiple switches, e.g., the power modification switches 561, 562).

The control circuit 560c may be configured to control a power supply voltage across the cell operation circuit 320 in accordance with a powering sequence, e.g., when initiating the read operation mode. The read operation mode may be initiated with the fourth operation phase, e.g., to set the cell operation circuit 320 into a state, in which the cell operation circuit 320 is configured to read the memory state from one or more memory cells 100a.

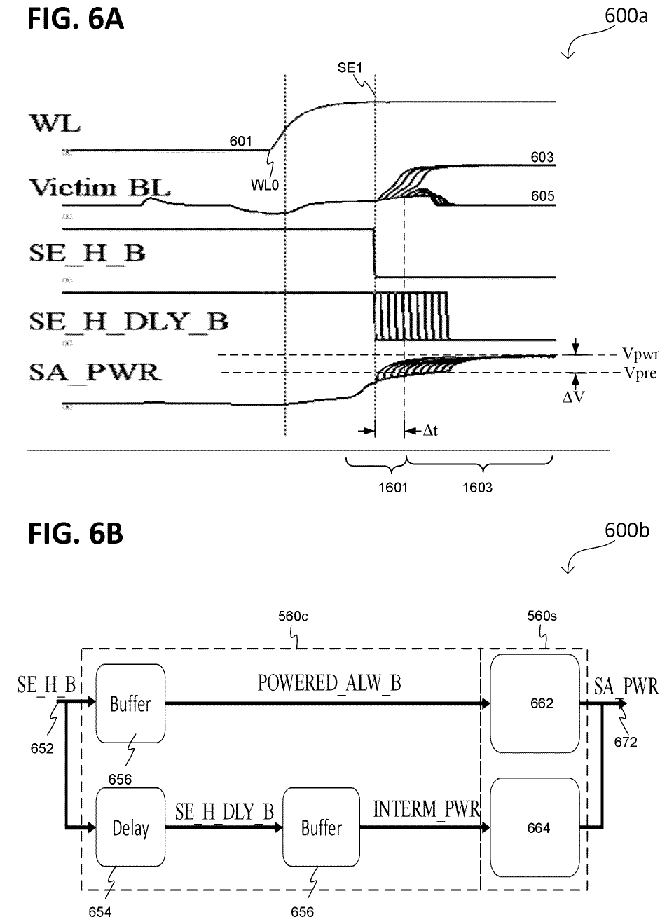

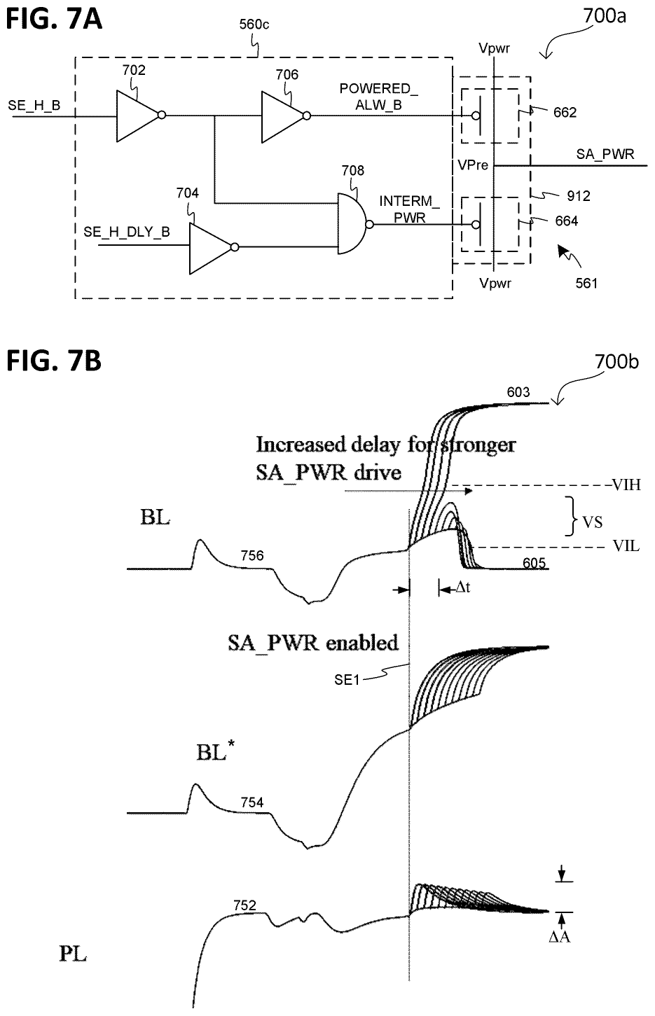

The powering sequence is detailed referring to FIG. 6A, showing an operation schema in a schematic diagram, detailing the time dependency of various signals, of which signal 601 denotes the voltage level of wordline, WL, and SA_PWR denotes the power supply voltage across the cell operation circuit 320, e.g., each latch 550 thereof. The powering sequence includes a first phase 1601, in which the power supply voltage, SA_PWR, is increased to a pre-charge voltage level Vpre being lower than the operation voltage level Vpwr, and a second phase, in which the power supply voltage, SA_PWR, is increased to the operation voltage level Vpwr (also referred to as read operation voltage level).

It is noted for the first phase 1601 that SA_PWR, illustratively, rises slow, e.g., with a controlled slope, which affects the coupling BL to BL and/or PL to BL, after the point of time SE1, e.g., being more controlled than the final Vpre/Vpwr value. As detailed in the next sections, the voltage modification rate (e.g., the slew rate), M, in the first phase 1601 the M is also not steep.

In the depicted example, the power supply voltage, SA_PWR, is increased stepwise, such that the rate (also referred to as voltage modification rate or as voltage change rate), with which the power supply voltage increases, changes at the transition from the first phase 1601 to the second phase 1603. As example, the voltage modification rate (e.g., the slew rate), M may be discontinuous at the transition from the first phase 1601 to the second phase 1603, but continuous within the first phase 1601 and the second phase 1603. The voltage modification rate, M, may be, for example, expressed as ΔV/Δt, or for a point of time as M=dV/dt, and may be, a function of time, thus being expressed as M=M(T). In this context, the terms “continuous” and “discontinuous” refer to the behavior of the function's graph from the mathematical perspective.

For example, the voltage modification rate (e.g., the slew rate), M, may decrease (e.g., exponentially and/or continuously) in the first phase 1601 to a first value (M1) at the end of the first phase 1601, which is less than a second value (M2) of the voltage modification rate at the beginning of the second phase 1603. For example, the M1<M2, e.g., M1<0.7·M2, e.g., M1<0.5·M2, e.g., M1<0.25·M2, e.g., M1<0.1·M2. Alternatively or additionally, M1 may be more than 10 V/μs (Volt per Microsecond) and or less than 100 V/μs, e.g., in the range between 30 V/μs and 50V/μs; and/or M2 may be more than 100 V/μs (Volt per Microsecond) and or less than 500 V/μs, e.g., in the range between 150 V/μs and 250 V/μs.

Alternatively or additionally, the voltage modification rate, M, may decrease (e.g., exponentially and/or continuously) in the second phase 1603 to a third value, M3, e.g., when the power supply voltage, SA_PWR, converges to Vpwr. The third value, M3, bm less than the first value, M1, and/or may be 0.

It may be understood that other implementations may apply in analogy, e.g., which increase the power supply voltage, SA_PWR, continuously at the transition from the first phase 1601 to the second phase 1603. It may be understood that other implementations may apply in analogy, e.g., which limit the voltage modification rate, M, to a maximum (also referred to as voltage modification rate limit) and/or to a range (also referred to as voltage modification rate range), which may be between M1 and M2 and/or between 10 V/μs (e.g., 30 V/μs, e.g., 100 V/μs) and the voltage modification rate limit. For example, the voltage modification rate limit may be less than 500 V/μs, e.g., less than 150 V/μs.

The array of curves represents multiple configurations for the length Δt of the first phase 1601 (also referred to as delay Δt or as time delay). A delay Δt below a delay threshold favors that the voltage level of the bitline coupled to the memory cell is increased abnormally (see lines 603), e.g., to the operation voltage level, that the memory cell will be read incorrectly. A delay Δt greater than the delay threshold inhibits the increase of the voltage level of the bitline coupled to the memory cell, such that the voltage level is decreased normally (see lines 605) and the memory cell will be read correctly.

The pre-charge voltage level, Vpre, may be generated by a first voltage source (also referred to as pre-charge voltage source), e.g., implemented by a first power supply. The operation voltage level Vpwr, may be generated by a second voltage source (also referred to as operation voltage source), e.g., implemented by a second power supply or by the first power supply. In some implementations, the pre-charge voltage source may be configured to provide pre-charge voltage level based on the operation voltage level Vpwr, for example, when the pre-charge voltage source includes a voltage divider and/or a RC-circuit.

The first phase 1601, in which the power supply voltage, SA_PWR, is increased to the pre-charge voltage level Vpre, delays the increase of the power supply voltage to the operation voltage level, Vpwr, which improves the read window through a better noise rejection; and/or reduces the affection of the read window is by a background pattern. In some embodiments, the delay Δt may be fixed or easily fine-tuned to provide the best trade-off between sense speed and reliability.

In some embodiments, the control circuit 560c may, for example, include a tuning circuitry configured to modify the length, Δt, of the first phase 1601. Alternatively or additionally, the tuning circuitry may be configured to modify the pre-charge voltage level and/or the voltage modification rate limit.

FIG. 6B shows a power modification circuit 560 in a schematic circuit diagram 600b. The power modification circuit 560 includes an input 652 for receiving a SE signal, SE_H_B, and an output 672 for supplying the power supply voltage, SA_PWR, to the cell operation circuit 320. The control circuit 560c includes an (e.g., tunable) delay circuitry 654 (also referred to as delay device), and, optionally one or more buffers. The multiple driver devices 560s include a first driver device 662 (illustratively a weak SA_PWR driver) and second driver device 664 (illustratively a strong SA_PWR driver). The delay circuitry 654 (e.g., a RC-delay circuitry) may be configured to provide a further SE signal, SE_H_DLY_B, e.g., as initiation signal and/or based on the SE signal, SE_H_B. The initiation signal may be delayed with respect to the SE signal, SE_H_B, e.g., by the delay Δt (see also FIG. 6A).

The first driver device 662 may be configured to increase the power supply voltage, SA_PWR, to the pre-charge voltage level, Vpre, based on the SE signal, SE_H_B, or, if a first buffer 656 receives the SE signal, SE_H_B, based on a buffered SE signal, POWERED_ALW_B. The buffered SE signal, POWERED_ALW_B, may be generated by the first buffer based on the SE signal, SE_H_B. The second driver device 664 may be configured to increase the power supply voltage, SA_PWR, to the operation voltage level Vpwr, based on the initiation signal, SE_H_DLY_B, or, if a second buffer 656 receives the initiation signal, SE_H_DLY_B, based on a buffered initiation signal, INTERM_PWR. The buffered initiation signal, INTERM_PWR may be generated by the second buffer based on the initiation signal, SE_H_DLY_B.

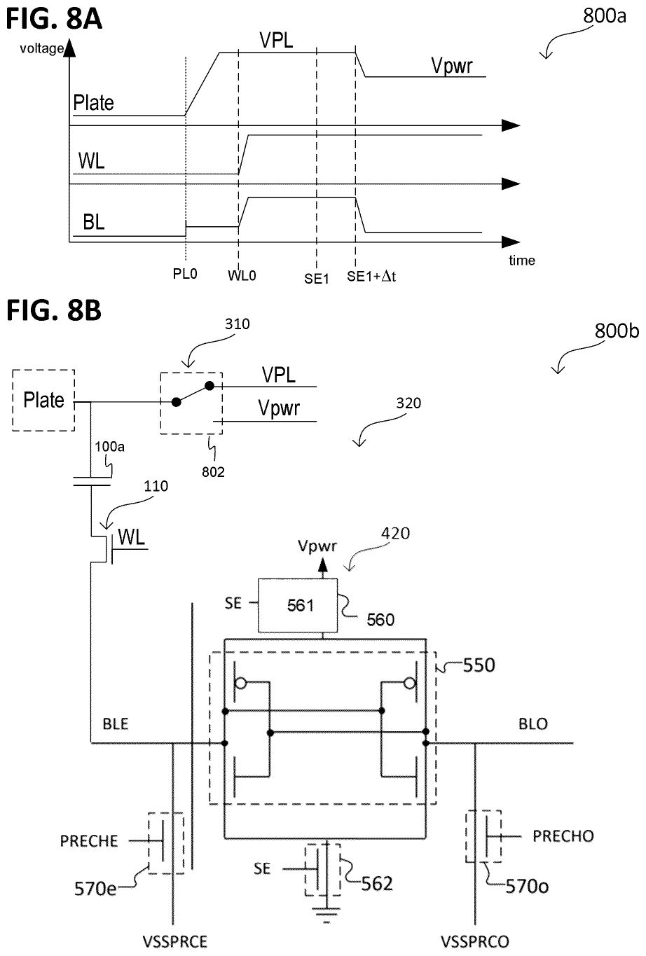

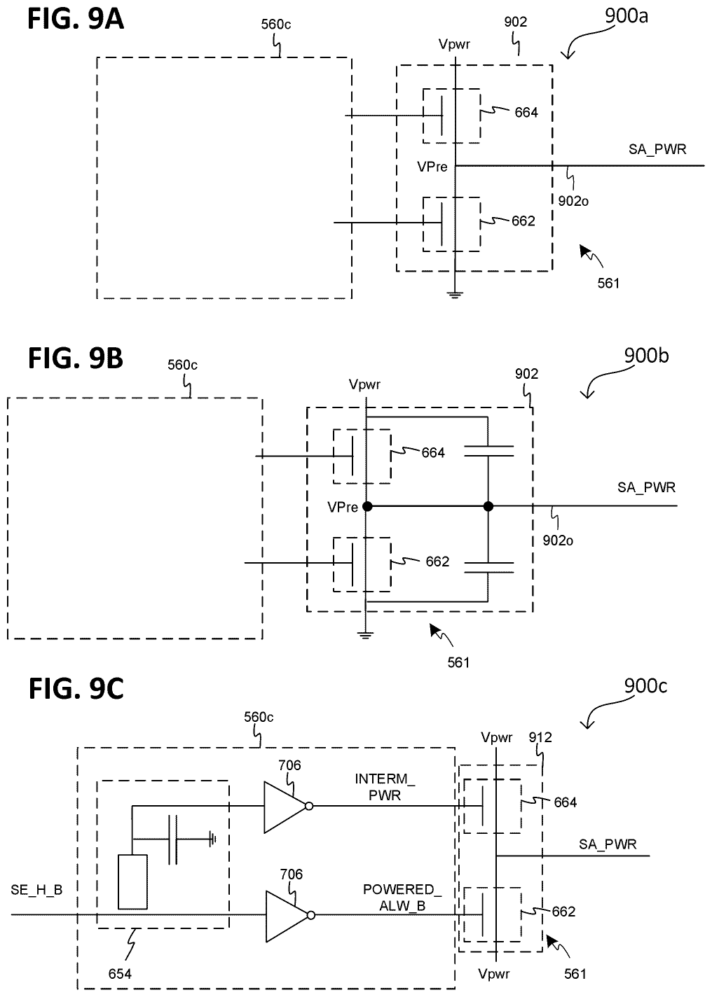

FIG. 7A shows an exemplarily implementation 700a of the power modification circuit 560 in a schematic circuit diagram, which includes: a first logic gate 702, which may be implemented by a first inverter 702 as detailed by FIG. 7A (or a NOR gate 1702, see FIG. 4), receiving the SE signal, SE_H_B. The circuit 560c further includes a second logic gate 704, which may be implemented by a second inverter 704 as detailed by FIG. 7 A (or a NOR gate 1704, see FIG. 4), receiving the initiation signal, SE_H_DLY_B. The circuit 560 further includes a third inverter 706 providing the buffered SE signal, POWERED_ALW_B, and a NAND gate 708 providing the buffered initiation signal, INTERM_PWR. The first driver device 662 may include or be made from a transistor (providing a first power modification switch 561) controlled by the buffered SE signal, POWERED_ALW_B and coupled to a source (also referred to as pre-charge voltage source) for the pre-charge voltage level, Vpre. The second driver device 664 may include or be made from a transistor (providing a second power modification switch 561) controlled by the buffered initiation signal, INTERM_PWR and coupled to a source (also referred to as operation voltage source) for the operation voltage level Vpwr.

The first driver device 662 and the second driver device 664 may implement a slope modifier 912, e.g., by differing from each other, such that the slope M may be modified. For example, the first driver device 662 and the second driver device 664 may differ from each other in their geometry and/or one or more electric properties, such as, for example, drive capability, switching characteristic, current capability, resistivity, threshold voltage and the like. In an exemplarily implementation, the first driver device 662 may be implemented by a “weak” transistor and the second driver device 664 may be implemented by a “strong” transistor. The terms “strong” and “weak” may refer to the strength of the transistors in pull-up (PMOS) and pull-down (NMOS) networks. For example, the “strong” transistor may have a stronger drive capability than the “weak” transistor. This allows to provide VPre by switching the “weak” transistor.

Other potential examples may include: a “strong” transistor having a lower threshold voltage (V_th) than the “weak” transistor; and/or a “strong” transistor having a larger width-to-length (W/L) ratio in the channel than the “weak” transistor; and/or a “strong” transistor having a lower on-resistance (R_on) than the “weak” transistor; and/or a “strong” transistor having a higher switching speed than the“weak” transistor.

A similar, but more complicated implementation 400 of the power modification circuit 560 is detailed in FIG. 4 in a schematic circuit diagram. For the depicted NOR gate based configuration, the first driver device 662 and the second driver device 664 mb provided by p-channel MOS.

Alternatively or additionally, e.g., Vpre and Vpwr provide two different supply voltage levels (Vpwr>Vpre), which allows the first driver device 662 and the second driver device 664 to be operated as multiplexer 922 to selectively forward Vpre or Vpwr. For example, the first driver device 662 may be disabled when the second driver device 664 is enabled and vice-versa.

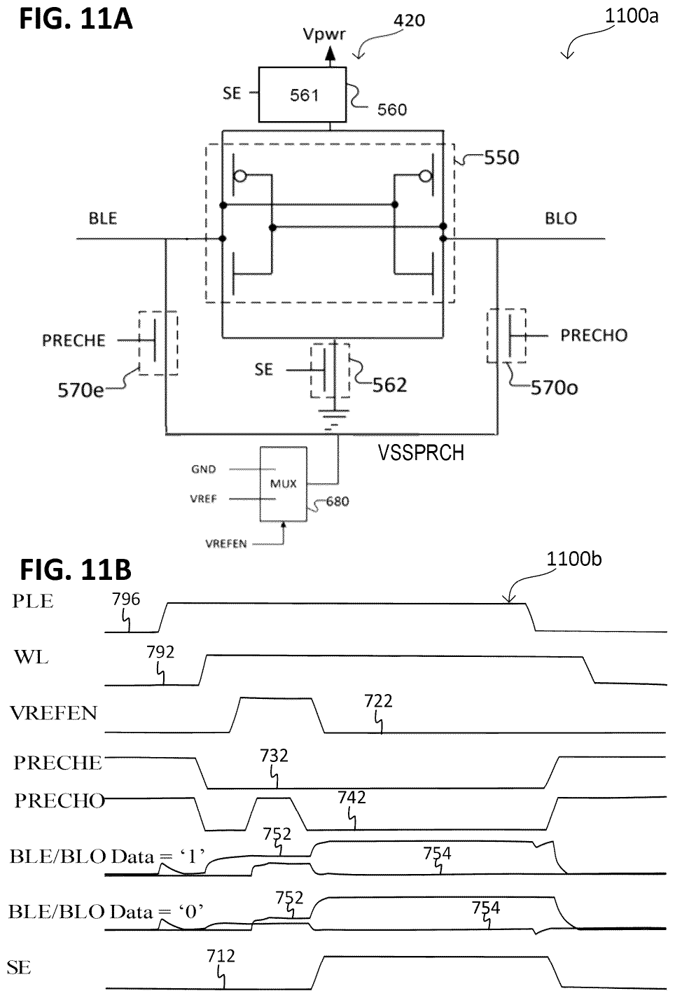

In another potential implementation (see also FIG. 9A), the first driver device 662 and the second driver device 664 may be operated as voltage divider 902, e.g., when the two different supply voltages do not fit the required needs.

The voltage divider 902 and the multiplexer 922 may understood as exemplarily options to replace the slope modifier 912, if required. The references made to FIG. 7 and FIG. 4 may apply in analogy to the other circuits detailed herein.

The signal SE_H_B may be provided as the inverted of signal SE, by inverting signal SE. For example, expressing the voltage U1 of signal SE_H_B as a function of time, U1=U1(t), and expressing the voltage U2 of signal SE as a function of time, U2=U2(t), the following relation may be fulfilled: U1(t) =−U2(t). Alternatively or additionally, signal SE_H_DLY_B may be provided as delayed copy of signal SE_H_B. For example, expressing the voltage U3 of signal SE_H_DLY_B as a function of time, U3=U3(t), and expressing the voltage U4 of signal SE_H_B as a function of time, U4=U4(t), the following relation may be fulfilled: U3(t+Δt)=U4(t).

For example, the SE signal, SE_H_B turns on a smaller PMOS of the first driver device 662 that controls the power supply voltage, SA_PWR (e.g., at the power terminal of the sense latches). A further SE signal, SE_H_DLY_B, being a delayed copy of the SE signal turns on a PMOS of the second device 664, which is stronger than the PMOS of the first device 662.

Illustratively, the latch is initially powered “softly”, so that the BL evolution is slow. In this condition the slew rate of the BL is not fast enough to cause a large glitch on the plate. The minority BL (“0”) evolves correctly as the positive coupling is absent or strongly attenuated by this powering sequence. When enough separation of the BL voltage level has been reached, the second and stronger pull up is enabled. As example, a trimmable delay for the SE_H_DLY_B signal may be provided.

FIG. 7B depicts another operation schema 700b, in which the time dependency of the voltage of the plateline (see line 752), of the second bitline, BL* (see line 754), and of the first bitline, BL (see line 756) is indicated as function of the delay Δt. Increasing the delay Δt reduces and delays a voltage swing ΔA developed at the plateline (see line 752), of the second bitline, BL* (see line 754), and/or of the first bitline, BL (see line 756). Further, increasing the delay Δt reduces the impact of the parasitic coupling of BL* with PL.

As visible from the curves, when the delay Δt is larger than a delay threshold, the abnormal voltage raise is prevented. As consequence, the voltage level of the first bitline coupled to a “0” cell is increased to a maximum (also referred to as voltage maximum) below the critical threshold level VIH. This prevents that the voltage level of the first bitline coupled to a “0” cell is increased abnormally.

For example, the voltage of the first bitline, BL (see line 756) reaches a voltage maximum (also referred to as BL spike) in the fourth operation phase, e.g., starting at or shortly after the point of time “SE1”. Alternatively or additionally, the voltage of the plateline, PL (see line 752) reaches a voltage maximum (also referred to as PL spike) in the fourth operation phase, e.g., starting at or shortly after the point of time “SE1”.

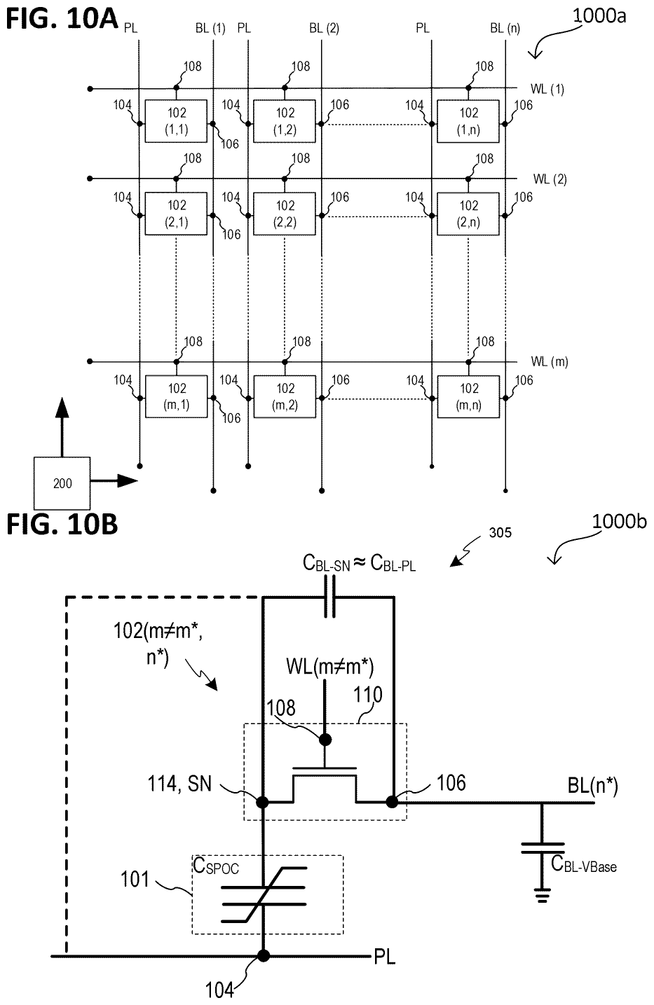

FIG. 8A depicts another operation schema 800a, in which the voltage of the plateline is increased to VPL starting at t=PL0 and before the voltage of the WL is increased at t=WL0. Further, the voltage of the plateline is decreased to the operation voltage level Vpwr after t=SE1.

FIG. 8B shows an exemplarily implementation 800b of device 200c or 500b (e.g., memory device) in a schematic circuit diagram, the device including the memory cell 100a, a cell operation circuit 320 (e.g., including a latch 550 as sense amplifier 420) coupled to the memory cell 100a via a bitline, BLE, a power modification circuit 560 including one or more power modification switches 561, 562, and a multiplexer 802 connecting the plate to a first node providing VPL or a second node the operation voltage level, Vpwr.

FIG. 9A shows an exemplarily implementation 900a of the power modification circuit 560 in a schematic circuit diagram, which generates the pre-charge voltage level Vpre using a voltage divider 902, of which the output terminal 902o provides the power supply voltage, SA_PWR. The voltage divider includes two transistors 662, 664 as power modification switches 561, which are coupled to each other by the output terminal 902o and which are coupled between the operation voltage level, Vpwr, and ground. The two transistors 662, 664 are controlled by the control circuit 560c in accordance with the powering sequence. The powering sequence includes a first phase, in which the two transistors 662, 664 are opened to increase the power supply voltage, SA_PWR, to the pre-charge voltage level, Vpre; and a second phase, in which transistor 662 is closed to increase the power supply voltage, SA_PWR, to the operation voltage level, Vpwr.

FIG. 9B shows another exemplarily implementation 900b of the power modification circuit 560 in a schematic circuit diagram, wherein the voltage divider 902 includes additional circuit elements (here exemplarily capacitors) to adjust the ratio of pre-charge voltage level, Vpre, to the operation voltage level, Vpwr. This configuration may also allow to remove one of the transistors 662, 664 of the voltage divider 902, which reduces the complexity of the control circuit 560c.

FIG. 9C shows yet another exemplarily implementation 900c of the power modification circuit 560 in a schematic circuit diagram, wherein the delay circuitry 654 of the control circuit 560c includes or is implemented by a series RC circuit. Optionally, the control circuit 560c may include one or more logic gates 702 (e.g., NOR gates or inverters) as detailed above, e.g., of which one is controlled by the series RC circuit. Generally, the NOR gates detailed herein are understood to be exemplarily implementations. For delaying the SE_H other implementation with logic gates may be implemented additionally or alternatively thereto.

The circuit architecture as shown in FIG. 9C may be used with Vpre=Vpwr, when using the slope modifier 912 instead of a voltage divider. The slope modifier 912 allows usage of different driver strength to change the voltage modification rate between different phases.

FIG. 10A an 10B show each an exemplary memory cell arrangement 1000a of a memory device and a detailed view 1000b thereof, the memory cell arrangement 1000a including a plurality of memory cells 102(m=1 to M, n=1 to N), of which each memory cell may be configured, for example, in analogy to memory cell 100a. It is understood that the memory device 1000a serves as an example to illustrate the aspects detailed herein and that the reference made thereto may apply in analogy to a memory device in any other suitable configuration.

A memory cell arrangement is usually configured in a matrix-type arrangement, wherein columns and rows define the addressing of the memory cells according to the control lines connecting respectively subsets of memory cells of the memory cell arrangement along the rows and columns of the matrix-type arrangement. However, other arrangements may be suitable as well. In general, a memory cell arrangement may include a plurality of (e.g., volatile or non-volatile) memory cells, which may be accessed individually or on groups via a corresponding addressing scheme. The matrix architecture may be, for example, referred to as “OR”, “AND”, “NOR”, or “NAND” architecture, depending on the way neighboring memory cells are connected to each other, i.e., depending on the way the terminals of neighboring memory cells are shared, but are not limited to these two types (another type is for example an “AND” architecture). For example, in a NAND architecture the memory cells may be organized in sectors (also referred to as blocks) of memory cells, wherein the memory cells are serially connected in a string (e.g., source and drain regions are shared by neighboring transistors), and the string is connected to a first control line and a second control line. For example, groups of memory cells in a NAND architecture may be connected in series with one another. In a NOR architecture the memory cells may be connected in parallel with one another. A NAND architecture may thus be more suited for serial access to data stored in the memory cells, whereas a NOR architecture may be more suited for random access to data stored in the memory cells.

The plurality of memory cells 102(m=1 to M, n=1 to N) may be arranged an array of N times M. “N” may be any integer number equal to or greater than one. “M” may be any integer number equal to or greater than one. In some aspects, the memory cell arrangement 100 may be in a ferroelectric random-access memory (FeRAM) configuration.

The depicted architecture of memory cell arrangement 1000a is understood as exemplary implementation for a facilitated understanding, not meant to be limiting. The referenced made hereto may apply in analogy to other architectures of a memory cell arrangement, e.g., including multiple platelines, e.g., of which the number may range from 1 to N*M depending on the chosen architecture. Examples of the number, N_PL, of platelines for implementing an architecture including m wordlines and n bitlines, may include: N_PL=1 (one plateline), N_PL=n, N_PL=m, N_PL=(m·n) or combinations thereof. The same applies to other memory cell arrangements as detailed herein in analogy.

The memory cell arrangement 100 may include a plurality of bitlines BL(n=1 to N), at least one plateline PL, and a plurality of wordlines WL(m=1 to M) for (individually and selectively) addressing the plurality of memory cells 102(m=1 to M, n=1 to N). Each memory cell 102(m*, n*) may be connected to and selectively (and individually) addressable via a corresponding bitline BL(n*) of the plurality of bitlines BL(n=1 to N), a corresponding wordline WL(m*) of the plurality of wordlines WL(m=1 to M), and the plateline PL. The *-notation may define one specific integer for the corresponding variable, such as a specific n* for the variable n, a specific m* for the variable m, etc.

In this exemplary configuration, each memory cell 102(m*, n*) may be a three-terminal memory cell having a first terminal 104, a second terminal 106, and a third terminal 108. The first terminal 104 of a respective memory cell 102(m*, n*) may be coupled to the corresponding plateline PL. The second terminal 106 of the respective memory cell 102(m*, n*) may be coupled to the corresponding bitline BL(n*). The third terminal 108 of the respective memory cell 102(m*, n*) may be coupled to the corresponding wordline WL(m*).

The memory cell arrangement 100 may include a controller 200 (in some aspects referred to as control circuit), e.g., implemented by the power modification circuit 560. The controller 200 may be configured to apply a respective voltage to each control line described herein. The control controller 200 may be configured to apply a plateline voltage, V_{PL}, (via the corresponding plateline PL) at the first terminal 104, a bitline voltage, V_{BL}, (via the corresponding bitline BL(n*)) at the second terminal 106, and a wordline voltage, V_{WL}, (via the corresponding wordline WL(m*)) at the third terminal 108 of the memory cell 102(m*, n*) in order to address the memory cell 102(m*, n*). The controller 200 may be configured to carry out a write operation to write a memory state of at least one memory cell 102(m*, n*). The controller 200 (e.g., including a read-out circuit) may be configured to initiate (e.g., carry out) a read-out operation to read out the memory state of the at least one memory cell 102(m*, n*).

“Writing” a memory cell, as used herein, may be understood as bringing the memory cell into one of at least two different memory states. Writing a memory cell may also be referred to as programming the memory cell, wherein the memory state the memory cell is residing in after programming may be called “programmed state”. Therefore, the memory cell may also be referred to as state-programmable memory cell.

“Reading” a memory cell, as used herein, may be understood as determining the memory state the memory cell is residing in (e.g., programmed to). In general, a memory cell may be read either non-destructively (if the read-out operation does not change the memory state the memory cell is residing in) or destructively (if the read-out operation changes the memory state the memory cell is residing in). Thus, a destructive read-out operation may require a write operation subsequent to read-out in order to program again the memory state of the memory cell.

FIG. 10B shows an equivalent circuit of a non-selected memory cell of memory cell arrangement 1000a. For those other memory cells 102(m=1 to M/*, n*), there may be a parasitic bitline to storage node (SN) capacitance, C_{BL-SN}, due to this coupling. Since for all non-selected (also referred to as unselected or deselected) memory cells the voltage at the storage node, SN, 114 is close to the plateline voltage, V_{PL}, the parasitic bitline to storage node capacitance C_{BL-SN} may be considered in the equivalent circuit as being directly connected to the plateline instead of the storage node 114 (see dashed line).

Illustratively, when reading a respective memory cell 102(m*, n*), there may be a parasitic bitline to storage node capacitance C_{BL-SN} between the corresponding bitline BL(n*) and the corresponding plateline PL via one or more of the non-selected other memory cells 102 (m=1 to M/*, n*), which are also coupled between the corresponding bitline BL(n*) and the corresponding plateline PL (see memory cells in a column in the memory cell arrangement 100). This case may be understood as example not limiting the underlying aspects. The coupling is generally dependent on the specific architecture, and may differ from case to case. For example for certain layouts, BL(1) may be coupled to the PL via memory cells 102(1,1), 102(1,2), 102(2,1), 102(2,2), . . . , 102(m,1), 102(m,2).

Analogously, the specific values of M, the parasitic bitline to storage node capacitance C_{BL-SN} and the capacitance of the selected memory cell may be a function of the specific architecture. For example, the parasitic bitline to storage node capacitance C_{BL-SN} may be less than the capacitance of the selected memory cell even with M lower than 100. Generally said, the parasitic bitline to storage node capacitance C_{BL-SN} increases with increasing M relative to the capacitance of the selected memory cell, e.g., exceeding the capacitance of the selected memory cell. In an exemplary case, the parasitic bitline to storage node capacitance C_{BL-SN} may be less than the capacitance of the selected memory cell (i.e., the memory cell which is read), e.g., when M is equal to or greater than one hundred (e.g., equal to or greater than five hundred, etc.). However, the sum of the parasitic capacitances of those M-1 other memory cells 102(m=1 to M/*, n*) may be even larger than the capacitance of the selected memory cell 102(m*, n*). Further, there may be a parasitic bitline to base voltage (e.g., ground voltage) capacitance C_{BL-VBASE} of the corresponding bitline BL(n*). With reference to FIG. 10B, some amount of the voltage the corresponding bitline BL(n*) is charged to during a read-out operation (i.e., part of ΔV₀ or ΔV₁) results from the parasitic capacitances of the non-selected memory cells 102(m=1 to M/*, n*).

The parasitic voltage developed on the corresponding bitline BL(n*) due to the parasitic capacitances may reduce the switching charge provided by the state-programmable memory element during a read operation. A reduced switching charge means that the read window (e.g., the difference between the developed voltage associated with a logic “0” and the developed voltage associated with a logic “1”) may be narrower and the read margin may be reduced, leading to potential read errors.

FIG. 11A shows a cell operation circuit 320 of a complementary type including a sense amplifier 420 in a schematic circuit diagram 1100a, which is an alternative to the architecture according to circuit diagram 300a, and FIG. 11B the corresponding operation schema in a schematic diagram, similar to FIG. 3B. In contrast to the architecture of the cell operation circuit 320 according to circuit diagram 300a, an even pre charge control (also referred as to PRECHE) may be used to control the even PRC transistor 570e, and an odd pre charge control (also referred as to PRECHO) may be used to control the odd PRC transistor 570o. Further, a common net voltage, VSSPRC, may be used for biasing both, the even bit line (BLE) and the odd bit line (BLO) via the PRC transistors.

Even and odd pre-charging transistors (570e, 570o) may be operated by the corresponding signals (PRECHE, PRECHO) that, when enabled, connect the corresponding bitline to the shared source voltage (VSSPRC) for charging and/or discharging the corresponding bitline. The even side bitline (BLE) and odd side bitline (BLO) may be pre-charged through corresponding pre-charging switches 570o, 570e to the common source voltage (VSSPRCH) that is configurable via a selection circuit 680, e.g., a multiplexer. For example, the common source voltage (VSSPRCH) may be configured to a ground voltage (GND) or a voltage reference (VREF). The selection circuit 680 may be controlled by a reference selection signal, VREFEN.

Further, the odd side plateline, PLO, is always deselected, e.g., being at logical “low”. The bit lines, BLE/BLO, are kept grounded through the PRC transistors 570e, 570o, e.g., until the disturbance initiated by the increasing PLE voltage is recovered. Further, the selected word line, WL, is opened, which causes a voltage to develop on the even bit line, BLE. Simultaneously, a reference voltage is applied to the odd bit line, BLO. Setting the sense enable control signal (SE) to logic “high” causes turning on the sense amplifier (SA), e.g., latch 550. As result, the reading operation may be conducted, e.g., by sensing a voltage difference by the SA. Implementing further aspects as detailed herein, e.g., the power modification circuit 560, improves the reading operation.

The third segment plots the reference selection signal (VREFEN, along line 722), which, for example, connects (via a selection circuit such as MUX 680), VSSPRCH to ground, when VREFEN is at logic low and to VREF when VREFEN is at logic high.

FIG. 12A shows a cell operation circuit 320 of a complementary type including a sense amplifier 420 in a schematic circuit diagram 1200a, which is an alternative to the architecture according to circuit diagram 300a and similar to that of circuit diagram 1100a. FIG. 12B show the respective operation schema in a schematic diagram. Additionally to the circuit diagram 1100a, both bit lines, BLO and BLE, are coupled to each other by a counter transistor 951, which is controlled by a counter control line (CNTPLSEN).

The odd side plateline, PLO, starts at logic “high” and the selected word line, WL, is opened. The bit lines, BLE/BLO, are kept grounded through PRC transistors until the disturbance initiated by the increasing PLO voltage is recovered. Next, the bit lines, BLE and BLO, are shorted through the counter transistor 951 by setting the counter control line to logic “high”. Next, the even plate line, PLE, and the odd plate line, PLO, are set to a counter-phase to cancel the dielectric contribution on the bit line, BL. As consequence, only a ferroelectric charge develops the voltage on the bit line, BL. Next, the counter transistor 951 is deactivated by setting the counter control line to logic high, and a reference voltage is applied only to the odd bit line, BLO. Setting the sense enable control signal (SE) to logic “high” causes turning on the sense amplifier (SA), e.g., latch 550. As result, the reading operation may be conducted, e.g., by sensing a voltage difference by the SA. Implementing further aspects as detailed herein, e.g., the power modification circuit 560, improves the reading operation.

As detailed above, separate signals at PRECHE/PRECHO and also separate signals at VSSPRCE/VSSPRCO at the same time is not needed necessarily, although may be used when required. Reducing the number of individual signals reduces control signal generator and/or layout levels, which reduces costs.

In the following, various examples are provided that may include one or more aspects described above with reference to a multilevel state-programable memory element. It may be intended that aspects described in relation to the circuits may apply also to the described method(s), and vice versa.

Example 1 is a memory device comprising: a set of memory cells provided in a plateline connected configuration; a cell operation circuit (also referred as to sense circuitry) coupled to a memory cell of the set via a bitline, wherein the cell operation circuit is configured, in a read operation mode, to read (e.g., a memory state, also referred as to programmed state) from the memory cell based on an operation voltage level; a control circuit configured to control a power supply voltage supplied to (e.g., a power input of) the cell operation circuit (e.g., in accordance with a powering sequence) when initiating the read operation mode, wherein the powering sequence includes preferably: a first phase, in which the power supply voltage is increased to a pre-charge voltage level being lower than the operation voltage level, and a second phase, in which the power supply voltage is increased to the operation voltage level (also referred to as read operation voltage level).

Example 2 is configured according to example 211, further comprising (e.g., a power modification circuit comprising) multiple switches (e.g., power modification switches) coupled in parallel to each other and/or coupled to (e.g., a power input of) the cell operation circuit, the multiple switches configured to be controlled (e.g., by the control circuit) and/or switched sequentially or at least independently from each other when initiating the read operation mode to modify a power supply voltage supplied to the power input.

Example 3 is a memory device (e.g., according to example 1 or 312), comprising: a set of memory cells provided in a plateline connected configuration; a cell operation circuit coupled to a memory cell of the set via a bitline, wherein the cell operation circuit is configured, in a read operation mode, to read (e.g., a memory state or programmed state) from the memory cell (e.g., based on an operation voltage level); a power modification circuit comprising multiple switches (e.g., power modification switches) coupled in parallel to each other and coupled to (e.g., a power input of) the cell operation circuit, the multiple switches configured to be switched sequentially or at least independently from each other when initiating the read operation mode to modify a power supply voltage supplied to the power input.

Example 4 is configured according to one of examples 422 or 43, further comprising the control circuit configured to control a power supply voltage supplied to (e.g., a power input of) the cell operation circuit, e.g., using the multiple switches and/or in accordance with a powering sequence when initiating the read operation mode, wherein the powering sequence includes: a first phase, in which the power supply voltage is increased to a pre-charge voltage level being lower than the operation voltage level, and a second phase, in which the power supply voltage is increased to the operation voltage level.

Example 5 is configured according to examples 2 to 54, wherein the control circuit is configured, to actuate (e.g., activate) a first switch, which is exposed to the pre-charge voltage level, of the multiple switches in the first phase; and/or wherein the control circuit is configured, to actuate (e.g., activate) a second switch, which is exposed to the operation voltage level, of the multiple switches in the second phase.

Example 6 is configured according to one of examples 2 to 65, wherein the control circuit is configured, to deactivate the first switch, which is exposed to the pre-charge voltage level, of the multiple switches in the second phase; and/or wherein the control circuit is configured, to deactivate the second switch, which is exposed to the operation voltage level, of the multiple switches in the first phase.

Example 7 is configured according to one of examples 1 to 716, wherein the power supply voltage is modified (e.g., increased) stepwise when initiating the read operation mode.

Example 8 is configured according to one of examples 1 to 817, wherein the power supply voltage is modified, in a first phase, by increasement to a pre-charge voltage level being lower than an operation voltage level of the cell operation circuit.

Example 9 is configured according to one of examples 1 to 918, wherein the power supply voltage is modified, in a second phase, by increasement (e.g., convergence) to an operation voltage level of the cell operation circuit.

Example 10 is configured according to one of examples 1 to 1019, wherein the second phase is delayed by the first phase and/or adjoins the first phase.

Example 11 is configured according to one of examples 1 to 11110, wherein the power supply voltage is increased stepwise when initiating the read operation mode.

Example 12 is configured according to one of examples 1 to 1211, further comprising one or more power supplies configured to provide multiple voltage levels (e.g., including the pre-charge voltage level and/or the operation voltage level), wherein the control circuit is configured to provide the power supply voltage based on the multiple voltage levels.

Example 13 is configured according to one of examples 1 to 1312, wherein the cell operation circuit is configured, in the read operation mode, to read from the memory cell (e.g., in a read operation) of the set, when the power supply voltage supplied to (e.g., a power input of) the cell operation circuit is at the read operation voltage level.

Example 14 is configured according to one of examples 1 to 1413, wherein the pre-charge voltage level is below a threshold allowing the cell operation circuit to read from the memory cell.

Example 15 is configured according to one of examples 1 to 1514, wherein the operation voltage level is above or equal to a threshold allowing the cell operation circuit to read from the memory cell.

Example 16 is configured according to one of examples 1 to 1615, further including a first voltage input to receive the pre-charge voltage level and/or a second voltage input to receive the operation voltage level.

Example 17 is configured according to example 1716, wherein the first switch is coupled in series between the first voltage input and the cell operation circuit; and/or wherein second switch is coupled in series between the second voltage input and the cell operation circuit.

Example 18 is configured according to one of examples 18216 to 1817, wherein the control circuit is configured to control the power supply voltage to (e.g., the pre-charge voltage) based on a first voltage level at the first voltage input and/or a second voltage level (e.g., operation voltage level) at the second voltage input.

Example 19 is configured according to one of examples 1 to 1918, wherein the control circuit includes a delay circuitry configured to supply, when initiating the read operation mode, an initiation signal to the first switch before supplying the initiation signal (or a delayed copy thereof) to the second switch.

Example 20 is a memory device (e.g., configured according to one of examples 1 to 2019), comprising: a set of memory cells provided in a plateline connected configuration; a cell operation circuit coupled to the set, wherein the cell operation circuit is configured, in a read operation mode, to read from a memory cell of the set, and, in a write operation mode, to write to the memory cell; a control circuit being configured to determine, whether the read operation mode or the write operation mode is initiated, and, based on a result thereof (also referred to as mode determination result), to control a power supply voltage (e.g., a modification rate thereof, e.g., a change rate) supplied to (e.g., a power input of) the cell operation circuit (e.g., with a lower rate and/or lower level).

Example 21 is configured according to example 21120, wherein the control circuit is configured to determine, whether a current operation mode is the read operation mode or write operation mode and to control the power supply voltage supplied to (e.g., a power input of) the cell operation circuit as a function of the current operation mode.

Example 22 is configured according to one of examples 22220 or 2221, wherein the power supply voltage (e.g., a voltage level thereof) in the read operation mode is less than in the write operation mode.

Example 23 is configured according to one of examples 23320 to 2322, further comprising one or more power supplies configured to provide multiple voltage levels (e.g., including an read operation voltage level and a write operation voltage level), wherein control circuit is configured to select one of the multiple voltage levels as power supply voltage based on the result.

Example 24 is configured according to one of examples 24420 to 2423, wherein a modification rate (e.g., a voltage difference per time) of the power supply voltage in the read operation mode is less than in the write operation mode.

Example 25 is configured according to one of examples 25520 to 2524, wherein a programmed state to write to the memory cell is based on a result of reading from the memory cell.

Example 26 is a circuit (e.g., configured according to one of examples 1 to 2625) comprising: a set of memory cells including a first memory cell connecting a first bitline to a plateline and a second memory cell connecting a second bitline to the plateline; a cell operation circuit coupled to the first bitline, wherein the cell operation circuit is configured, in a read operation mode, to read from the first memory cell; a control circuit being configured to control a power supply voltage supplied to (e.g., a power input of) the cell operation circuit when initiating the read operation mode, such that, when a programmed state of the first memory cell is low and a programmed state of the second memory cell is high, an increase of a voltage level of the first bitline promoted by a coupling of the first bitline and the second bitline via the plateline, is, in the read operation mode, below a threshold, at which the cell operation circuit reads the programmed state of the first memory cell to be high.

Example 27 is configured according to one of examples 1 to 2726, further comprising a plateline and a set of bitlines, wherein, in the plateline connected configuration, each memory cell couples the plateline to one bitline of the set of bitlines.

Example 28 is configured according to one of examples, wherein the set comprises a plurality of memory cells, oh which each memory cell couples the cell operation circuit with a plateline.

Example 29 is configured according to one of examples, further comprising a plateline coupled to each a plurality of memory cells of the set.

Example 30 is configured according to one of examples, further comprising, for each memory cell of a plurality of memory cells of the set, a bitline coupling the memory cell with the cell operation circuit.

Example 31 is configured according to one of examples, wherein the read operation mode is in accordance with an all bitline configuration.

Example 32 is configured according to one of examples, wherein the control circuit is configured to initiate charging (e.g., increase a voltage of) the plateline when initiating the read operation mode (e.g., activating the sense circuit).

Example 33 is configured according to one of examples, wherein the memory cell includes a spontaneous polarizable material, e.g., a ferroelectric material or a antiferroelectric material.

Example 34 is configured according to example 3433, wherein the memory cell includes two electrodes, between which the spontaneous polarizable material is arranged.

Example 35 is configured according to example 3534, wherein the two electrodes include a first electrode and a second electrode, which is arranged within the first electrode.

Example 36 is configured according to one of examples 1 to 3635, wherein the memory cell includes a capacitive memory structure (also referred as to memory capacitor).

Example 37 is configured according to one of examples 1 to 3736, wherein the read operation mode comprises a (e.g., destructive) read operation of one or more memory cells of the set.

Example 38 is configured according to one of examples 1 to 3837, wherein the cell operation circuit includes one or more sense amplifiers, e.g., for each memory cell of a plurality of memory cells of the set, a sense amplifier coupled to the memory cell.

Example 39 is configured according to one of examples 1 to 3938, wherein the read operation mode comprises a (e.g., destructive) read operation carried out by the cell operation circuit, wherein the power supply voltage is increased (e.g., stepwise) to initiate the read operation.

Example 40 is configured according to one of examples 1 to 4039, wherein the write operation mode comprises a write operation of one or more memory cells of the set.

Example 41 is configured according to one of examples 1 to 4140, wherein the power supply voltage is modified in the first phase with a lower rate that in the second phase.

Example 42 is configured according to one of examples 1 to 4241, wherein, in the read operation mode, a voltage level supplied to the plateline is higher than the read operation voltage level.

Example 43 is configured according to one of examples 1 to 4342, wherein, after the read operation mode, a voltage level supplied to the plateline is the read operation voltage level.

Example 44 is configured according to one of examples 1 to 4443, wherein the control circuit includes a delay circuitry configured to delay the second phase, when initiating the read operation mode.

Example 45 is configured according to one of examples 1 to 4544, wherein the control circuit includes a delay signal input (e.g., configured to receive a delay signal) and is configured to initiate the second phase and/or control the timing of the second phase based on the delay signal received at the delay signal input.

Example 46 is configured according to one of examples 1 to 4645, wherein the control circuit includes a delay signal input (e.g., configured to receive a delay signal) and is configured to initiate the second phase and/or control the timing of the second phase based on the delay signal received at the delay signal input.

Example 47 is configured according to one of examples 1 to 4746, wherein the control circuit includes a delay signal input (e.g., configured to receive a delay signal) and is configured to control a modification rate (e.g., slew rate) of the power supply voltage in the read operation mode based on the delay signal received at the delay signal input.

Example 48 is configured according to one of examples 1 to 4847, wherein, when the memory cell is programmed with a first (e.g., “0”) state of the memory cell, which is assigned to a first (e.g., low) read voltage level, a voltage of the bitline passes, in the second phase, a voltage maximum (e.g., spike) before dropping to the first read voltage level, wherein, preferably, the voltage maximum is below a threshold (e.g., intermediate voltage), which causes the voltage of the bitline to raise to a second (e.g., high) read voltage level, which is assigned to a second state of the memory cell.

Example 49 is configured according to example 1 to 4948, wherein the voltage maximum is below a threshold (e.g., intermediate voltage), above which the cell operation circuit triggers (e.g., causes) an increase of the voltage of the bitline to the second (e.g., high) read voltage level, which is assigned to a second state of the memory cell and/or more than the first read voltage level and/or the threshold.

Example 50 is configured according to one of examples 1 to 5049, wherein, when the memory cell is programmed with a second (e.g., “1”) state of the memory cell, which is assigned to a second (e.g., high) read voltage level, a voltage of the bitline passes, in the second phase, increases to the second read voltage level.

Example 51 is configured according to one of examples 1 to 5150, wherein the cell operation circuit is configured, in the read operation mode, to determine a first (e.g., “0”) state of the memory cell as programmed state of the memory cell, when a voltage of the bitline drops to a first read voltage level in the second phase.

Example 52 is configured according to one of examples 1 to 5251, wherein the cell operation circuit is configured, in the read operation mode, to determine a second (e.g., “1”) state of the memory cell as programmed state of the memory cell, when the voltage of the bitline reaches a second read voltage level in the second phase, the second read voltage level being more then the first read voltage level.

Example 53 is configured according to one of examples 1 to 5352, wherein each cell of the set of memory cells (e.g., provided in the plateline connected configuration) is connected to a plateline and/or includes the spontaneous polarizable material.

Example 54 is configured according to one of examples 1 to 5453, wherein a voltage level of the plateline in the read operation mode is above the operation voltage level.

Example 55 is configured according to one of examples 1 to 5554, wherein a modification rate (also referred to as voltage modification rate (e.g., slew rate), e.g., expressed as volts per second) of the power supply voltage in the first phase (e.g., the end thereof) and the second phase (e.g., the beginning) differs from each other.

Example 56 is configured according to one of examples 1 to 5655, wherein a modification rate (e.g., slew rate) of the power supply voltage increases (e.g., jumps discontinuously) at the transition from the first to the second phase (e.g., when entering, e.g., from the first phase to, the second phase).

Example 57 is configured according to one of examples 1 to 5756, wherein a modification rate (e.g., slew rate) of the power supply voltage is discontinuous at the transition from the first phase to the second phase.

Example 58 is configured according to one of examples 1 to 5857, wherein a modification rate (e.g., slew rate) of the power supply voltage is continuous in the first phase and/or the second phase.

Example 59 is configured according to one of examples 1 to 5958, wherein a modification rate (e.g., slew rate) of the power supply voltage at the end of the first phase is less than the modification rate (e.g., slew rate) of the power supply voltage at the beginning of the second phase.

Example 60 is configured according to one of examples 1 to 6059, wherein the second phase is longer than the first phase.

Example 61 is configured according to one of examples 1 to 6160, wherein a modification rate (e.g., slew rate) of the power supply voltage at the end of the first phase is more than a modification rate (e.g., slew rate) of the power supply voltage at the end of the second phase.

Example 62 is configured according to one of examples 1 to 6261, wherein the power supply voltage converges to the operation voltage level at the end of the second phase.

Example 63 is configured according to one of examples 1 to 6362, wherein the pre-charge voltage level more than 10% (e.g., 25%, e.g., 50%) of the operation voltage level and/or less than 90% (e.g., 75%) of the operation voltage level.

Example 64 is configured according to one of examples 1 to 6463, wherein the control circuit includes a delay circuitry providing a time delay, wherein the length of the first phase is a function of the time delay and/or wherein the (e.g., pre-charge) voltage level of the power supply voltage at the end of the first phase is a function of the time delay.

Example 65 is configured according to one of examples 1 to 6564, wherein the power supply voltage reaches the pre-charge voltage level at the end of the first phase.

Example 66 is configured according to one of examples 1 to 6665, wherein the power supply voltage reaches the operation voltage level at the end of the second phase.

Example 67 is configured according to one of examples 1 to 6766, wherein the multiple switches include a first switch coupled between a first voltage input for receiving a pre-charge voltage level and the cell operation circuit; wherein the multiple switches comprise a second switch coupled between a second voltage input for receiving the operation voltage level and the cell operation circuit, wherein the pre-charge voltage level is less than the operation voltage level.

Example 68 is configured according to one of examples 1 to 6866, further including a power modification circuit comprising multiple switches coupled in parallel to each other and coupled to the cell operation circuit, the multiple switches configured to be controlled sequentially or at least independently from each other by the control circuit based on the mode determination result.

The terms “at least one” and “one or more” may be understood to include any integer number greater than or equal to one, i.e. one, two, three, four, [. . . ], etc. is the term “a plurality” or “a multiplicity” may be understood to include any integer number greater than or equal to two, i.e. two, three, four, five, [. . . ], etc. is the phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A memory device, comprising:
a set of memory cells provided in a plateline connected configuration;
a cell operation circuit coupled to a memory cell of the set via a bitline, wherein the cell operation circuit is configured, in a read operation mode, to read from the memory cell based on an operation voltage level;
a control circuit configured to control a power supply voltage supplied to the cell operation circuit in accordance with a powering sequence when initiating the read operation mode, wherein the powering sequence comprises:
a first phase, in which the power supply voltage is increased to a pre-charge voltage level being lower than the operation voltage level, and
a second phase, in which the power supply voltage is increased to the operation voltage level.

2. The memory device of claim 211, further comprising multiple switches coupled in parallel to each other and coupled to the cell operation circuit, the multiple switches configured to be controlled sequentially or at least independently from each other by the control circuit when initiating the read operation mode to modify the power supply voltage supplied to the power input.

3. The memory device of claim 32, wherein the control circuit is configured, to actuate a first switch, which is exposed to the pre-charge voltage level, of the multiple switches in the first phase; and to actuate a second switch, which is exposed to the operation voltage level, of the multiple switches in the second phase.

4. The memory device of one of claims 43, wherein the control circuit is configured to deactivate the first switch, which is exposed to the pre-charge voltage level, of the multiple switches in the second phase; and wherein the control circuit is configured, to deactivate the second switch, which is exposed to the operation voltage level, of the multiple switches in the first phase.

5. The memory device of claim 1, wherein a modification rate of the power supply voltage in the first phase differs from the modification rate of the power supply voltage in the second phase.

6. The memory device of claim 1, wherein a modification rate of the power supply voltage increases when entering the second phase

7. The memory device of claim 1, wherein the control circuit comprises a delay signal input and is configured to control a timing of the second phase based on a delay signal received at the delay signal input.

8. The memory device of claim 1, further comprising one or more power supplies configured to provide multiple voltage levels, wherein the control circuit is configured to provide the power supply voltage based on the multiple voltage levels.

9. The memory device of claim 1, wherein the pre-charge voltage level is below a threshold allowing the cell operation circuit to read from the memory cell; and wherein the operation voltage level is above or equal to the threshold.

10. The memory device of claim 1, further including a first voltage input to receive the pre-charge voltage level and a second voltage input to receive the operation voltage level, wherein the control circuit is configured to control the power supply voltage based on a first voltage level at the first voltage input and a second voltage level at the second voltage input.

11. The memory device of claim 1, wherein the memory cell comprises a spontaneous polarizable material.

12. The memory device of claim 1, wherein, when a programmed state of the memory cell is a first state, which is assigned to a first read voltage level, a voltage of the bitline passes, in the second phase, a voltage maximum before dropping to the first read voltage level.

13. The memory device of claim 1312, wherein the voltage maximum is below a threshold, above which the cell operation circuit triggers the voltage of the bitline to increase to a second read voltage level above the threshold.

14. A memory device, comprising:
a set of memory cells provided in a plateline connected configuration;
a cell operation circuit coupled to a memory cell of the set via a bitline, wherein the cell operation circuit is configured, in a read operation mode, to read from the memory cell based on an operation voltage level;
a power modification circuit comprising multiple switches coupled in parallel to each other and coupled to the cell operation circuit, the multiple switches configured to be switched sequentially or at least independently from each other when initiating the read operation mode to modify a power supply voltage supplied to the power input.

15. The memory device of claim 1514, wherein the multiple switches comprise a first switch coupled between a first voltage input for receiving a pre-charge voltage level and the cell operation circuit; wherein the multiple switches comprise a second switch coupled between a second voltage input for receiving the operation voltage level and the cell operation circuit, wherein the pre-charge voltage level is less than the operation voltage level.

16. A memory device comprising:
a set of memory cells provided in a plateline connected configuration;
a cell operation circuit to a memory cell of the set via a bitline, wherein the cell operation circuit is configured, in a read operation mode, to read from a memory cell of the set, and, in a write operation mode, to write to the memory cell;
a control circuit being configured to determine, whether the read operation mode or write operation mode is initiated, and, based on a result thereof, to control a power supply voltage supplied to the cell operation circuit.

17. The memory device of claim 17116, wherein a voltage level of the power supply voltage in the read operation mode is less than the voltage level of the power supply voltage in write operation mode.

18. The memory device of claim 18216, wherein a modification rate of the power supply voltage in the read operation mode is less than the modification rate of the power supply voltage in the write operation mode.

19. The memory device of claim 19316, wherein the control circuit comprises a delay signal input to receive a delay signal and is configured to control a modification rate of the power supply voltage in the read operation mode based on the delay signal received at the delay signal input.

20. The memory device of claim 20416, further comprising a power modification circuit comprising multiple switches coupled in parallel to each other and coupled to the cell operation circuit, the multiple switches configured to be controlled sequentially or at least independently from each other by the control circuit based on the result to control the power supply voltage supplied to the cell operation circuit.
